(19) United States
(12) Patent Application Publication
(10) Pub. No.: US 2021/0213992 A1
(43) Pub. Date: Jul. 15, 2021

(54) HEIGHT-ADJUSTABLE, MOTORIZED TRANSPORTATION TOTE

(71) Applicant: Dell Products L.P., Round Rock, TX (US)

(72) Inventors: James Don CURLEE, Round Rock, TX (US); Steven EMBLETON, Austin, TX (US); Joshua Scott KEUP, Austin, TX (US); Ben John SY, Austin, TX (US)

(73) Assignee: Dell Products L.P., Round Rock, TX (US)

(21) Appl. No.: 16/743,426

(22) Filed: Jan. 15, 2020

(51) Int. Cl. B62B 5/00; H05K 7/14; H05K 7/18; B62B 3/02

(52) U.S. Cl. CPC B62B 5/0033; H05K 7/1488; H05K 7/18; B62B 2203/10; B62B 5/0089; B62B 2202/56; B62B 3/02

(57) ABSTRACT

An apparatus may include an enclosure that includes a plurality of mounting features that are configured to receive information handling systems. A base may be disposed below the enclosure, coupled to the enclosure, and may include a plurality of wheels. The base may be coupled to the enclosure via a height adjustment mechanism configured to lower and raise the enclosure relative to the base.

### TECHNICAL FIELD

The present disclosure relates in general to information handling systems, and more particularly to the transportation of information handling systems.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Various problems are known in the field of transportation and delivery of information handling systems, particularly in the enterprise context of rack-mounted systems including a plurality of standard-sized server information handling systems. Currently, integrated rack solutions are typically delivered to customers on a wooden pallet with foam (e.g., extruded polystyrene foam) to mitigate shock events. The shipping environment is extremely harsh, and integrated rack solutions can see significant forces, causing damage to the rack or the internal equipment. Further, existing solutions tend to involve large quantities of single-use packing and shipping materials that must be discarded after delivery.

This application is related to U.S. application Ser. No. 16/681,336 (Attorney Docket No. 102450.00614), filed Nov. 12, 2019, which is incorporated by reference herein in its entirety. That application discusses in detail various embodiments of shippable “totes” that may be used as an all-in-one solution to dampen shock events via shock absorbers and/or isolators fully integrated into a server rack.

The present application addresses more specifically issues that may arise while moving such totes (e.g., loading totes into trucks or shipping containers, moving them around within a datacenter, etc.). For example, totes may be relatively tall, which can cause clearance issues with low ceilings, doorways, and the like. Accordingly, it would be advantageous to be able to lower the profile of a tote while passing through a low-clearance area.

On the other hand, constructing a tote that is always at its lowest possible height may present different challenges. For example, passing over a threshold or floor transition may be difficult if a tote has insufficient ground clearance. Accordingly, it may be advantageous to be able to raise the tote while passing over such obstacles, but lower the tote when passing through areas of low overhead clearance.

Additionally, while some embodiments may employ un-powered casters to allow totes to roll, other embodiments may be motorized. For example, one or more motors may be coupled to the wheels/casters of a tote. Such motorization may also aid in moving totes.

The use of techniques according to this disclosure may provide many benefits. It should be noted that for the sake of concreteness, this application describes the use of totes. However, one of ordinary skill in the art will appreciate its applicability to other designs as well.

It should also be noted that the discussion of a technique in the Background section of this disclosure does not constitute an admission of prior-art status. No such admissions are made herein, unless clearly and unambiguously identified as such.

### SUMMARY

In accordance with the teachings of the present disclosure, the disadvantages and problems associated with transportation of information handling systems may be reduced or eliminated.

In accordance with embodiments of the present disclosure, an apparatus may include an enclosure that includes a plurality of mounting features that are configured to receive information handling systems. A base may be disposed below the enclosure, coupled to the enclosure, and may include a plurality of wheels. The base may be coupled to the enclosure via a height adjustment mechanism configured to lower and raise the enclosure relative to the base.

In accordance with these and other embodiments of the present disclosure, a method may include forming an enclosure that includes a plurality of mounting features that are configured to receive information handling systems; and coupling a base to the enclosure, wherein the base is disposed below the enclosure and includes a plurality of wheels. The base may be coupled to the enclosure via a height adjustment mechanism configured to lower and raise the enclosure relative to the base.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a block diagram of an example information handling system, in accordance with embodiments of the present disclosure;

FIG. 2A illustrates a front view of an example transportation apparatus, in accordance with embodiments of the present disclosure;

FIG. 2B illustrates a side view of the embodiment of FIG. 2A;

FIG. 2C illustrates a perspective view of the embodiment of FIG. 2A;

FIG. 3 illustrates a front view of another example transportation apparatus, in accordance with embodiments of the present disclosure;

FIGS. 4A and 4B illustrate front views of example height-adjustable transportation apparatuses, in accordance with embodiments of the present disclosure; and

FIGS. 5A and 5B illustrate side views of example motorized transportation apparatuses, in accordance with embodiments of the present disclosure.

### DETAILED DESCRIPTION

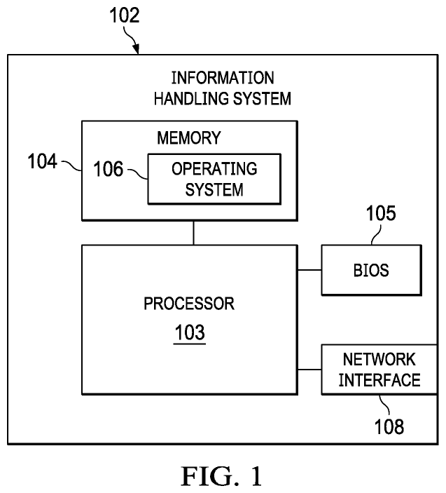

Preferred embodiments and their advantages are best understood by reference to FIGS. 1 through 5B, wherein like numbers are used to indicate like and corresponding parts.

For the purposes of this disclosure, the term “information handling system” may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a personal digital assistant (PDA), a consumer electronic device, a network storage device, or any other suitable device and may vary in size, shape, performance, functionality, and price. The information handling system may include memory, one or more processing resources such as a central processing unit (“CPU”) or hardware or software control logic. Additional components of the information handling system may include one or more storage devices, one or more communications ports for communicating with external devices as well as various input/output (“I/O”) devices, such as a keyboard, a mouse, and a video display. The information handling system may also include one or more buses operable to transmit communication between the various hardware components.

For purposes of this disclosure, when two or more elements are referred to as “coupled” to one another, such term indicates that such two or more elements are in electronic communication or mechanical communication, as applicable, whether connected directly or indirectly, with or without intervening elements.

When two or more elements are referred to as “coupleable” to one another, such term indicates that they are capable of being coupled together.

For the purposes of this disclosure, the term “computer-readable medium” (e.g., transitory or non-transitory computer-readable medium) may include any instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory; communications media such as wires, optical fibers, microwaves, radio waves, and other electromagnetic and/or optical carriers; and/or any combination of the foregoing.

For the purposes of this disclosure, the term “information handling resource” may broadly refer to any component system, device, or apparatus of an information handling system, including without limitation processors, service processors, basic input/output systems, buses, memories, I/O devices and/or interfaces, storage resources, network interfaces, motherboards, and/or any other components and/or elements of an information handling system.

FIG. 1 illustrates a block diagram of an example information handling system 102, in accordance with embodiments of the present disclosure. In some embodiments, information handling system 102 may comprise a server chassis configured to house a plurality of servers or “blades.” In other embodiments, information handling system 102 may comprise a personal computer (e.g., a desktop computer, laptop computer, mobile computer, and/or notebook computer). In yet other embodiments, information handling system 102 may comprise a storage enclosure configured to house a plurality of physical disk drives and/or other computer-readable media for storing data (which may generally be referred to as “physical storage resources”). As shown in FIG. 1, information handling system 102 may comprise a processor 103, a memory 104 communicatively coupled to processor 103, a BIOS 105 (e.g., a UEFI BIOS) communicatively coupled to processor 103, a network interface 108 communicatively coupled to processor 103. In addition to the elements explicitly shown and described, information handling system 102 may include one or more other information handling resources.

Processor 103 may include any system, device, or apparatus configured to interpret and/or execute program instructions and/or process data, and may include, without limitation, a microprocessor, microcontroller, digital signal processor (DSP), application specific integrated circuit (ASIC), or any other digital or analog circuitry configured to interpret and/or execute program instructions and/or process data. In some embodiments, processor 103 may interpret and/or execute program instructions and/or process data stored in memory 104 and/or another component of information handling system 102.

Memory 104 may be communicatively coupled to processor 103 and may include any system, device, or apparatus configured to retain program instructions and/or data for a period of time (e.g., computer-readable media). Memory 104 may include RAM, EEPROM, a PCMCIA card, flash memory, magnetic storage, opto-magnetic storage, or any suitable selection and/or array of volatile or non-volatile memory that retains data after power to information handling system 102 is turned off.

As shown in FIG. 1, memory 104 may have stored thereon an operating system 106. Operating system 106 may comprise any program of executable instructions (or aggregation of programs of executable instructions) configured to manage and/or control the allocation and usage of hardware resources such as memory, processor time, disk space, and input and output devices, and provide an interface between such hardware resources and application programs hosted by operating system 106. In addition, operating system 106 may include all or a portion of a network stack for network communication via a network interface (e.g., network interface 108 for communication over a data network). Although operating system 106 is shown in FIG. 1 as stored in memory 104, in some embodiments operating system 106 may be stored in storage media accessible to processor 103, and active portions of operating system 106 may be transferred from such storage media to memory 104 for execution by processor 103.

Network interface 108 may comprise one or more suitable systems, apparatuses, or devices operable to serve as an interface between information handling system 102 and one or more other information handling systems via an in-band network. Network interface 108 may enable information handling system 102 to communicate using any suitable transmission protocol and/or standard. In these and other embodiments, network interface 108 may comprise a network interface card, or “NIC.” In these and other embodiments, network interface 108 may be enabled as a local area network (LAN)-on-motherboard (LOM) card.

As discussed above, various problems are known in the art of transportation and delivery of information handling systems (e.g., information handling system 102). Accordingly, a transportation apparatus referred to herein as a tote may be used as an all-in-one solution that dampens shock events via shock absorbers and/or isolators fully integrated into a server rack, having a ship loadable design. Such a tote may be made of any suitable material (e.g., steel).

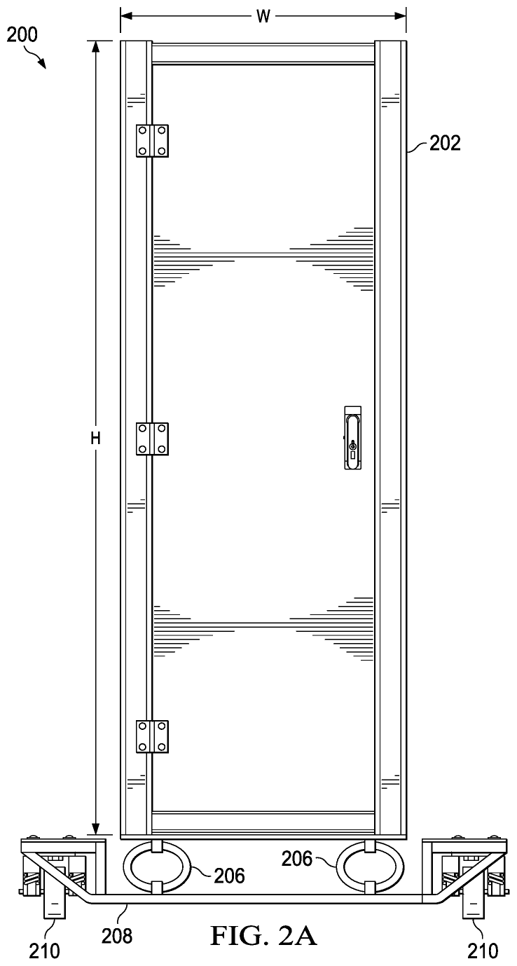

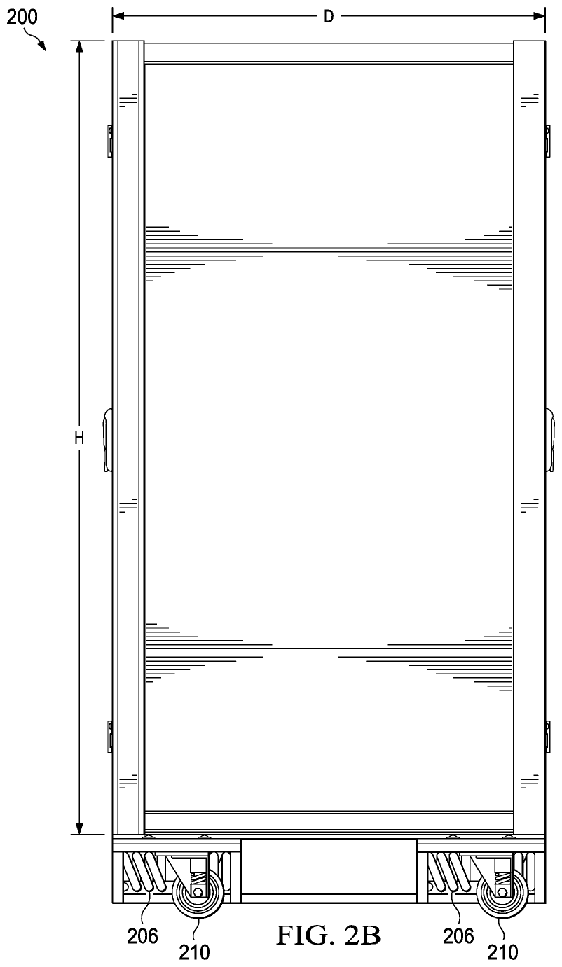

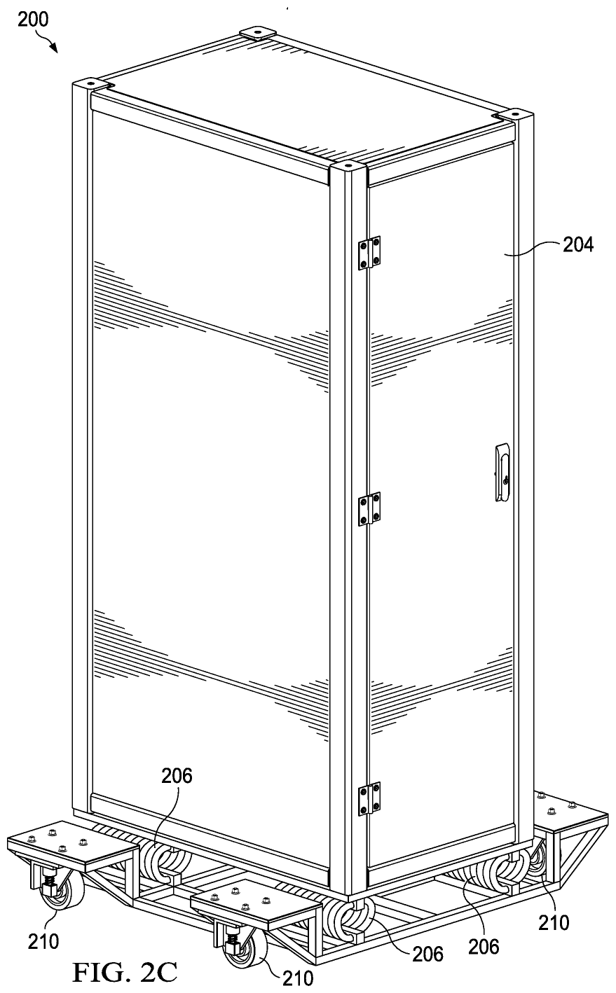

Turning now to FIGS. 2A-2C, several views are shown of an example tote 200. Tote 200 includes an enclosure portion 202 coupled on top of a base portion 208. Enclosure portion 202 may include a door 204 and a rack (not explicitly shown in these views) for receiving a plurality of information handling systems such as information handling system 102. In some embodiments, the rack may be manufactured according to a standard such as EIA-310, which defines standard rack unit sizing. For example, the embodiment shown at tote 200 may be sized to accommodate 40 rack units worth of information handling systems. In other embodiments, different sizes may be used such as 21-inch server equipment, laptops, desktops, other types of information handling systems, or information handling resources such as internet-of-things (IOT) hardware, hard drives, monitors, etc.

In some embodiments, tote 200 may be usable only for transport of information handling systems (e.g., it may not be configured for powering and operating such systems while they are received in the rack).

The rack may be isolated from vibrations during transit via the use of isolators 206. In various embodiments, isolators 206 may be wire rope, elastomeric, or any other suitable type of isolator. In the embodiment shown, isolators 206 are of the wire rope type. In some embodiments, tote 200 may also include lateral shock absorbers for protection from bumps that it may experience during integration and transportation (e.g., running into other racks, walls, truck walls, etc.).

Base portion 208 may also include casters 210 (e.g., four casters 210), which may be installed in an “outrigger” configuration. For example, enclosure portion 202 has a height H, a width W, and a depth D as shown. The width and the depth may define a footprint for enclosure portion 202, and casters 210 may be disposed in positions that are laterally displaced such that they reside outside of the footprint of enclosure portion 202. In the embodiment shown, casters 210 may be shock-absorbing casters. For example, they may have integral shock dampers and/or may be mounted on shock-damping mounts.

The outrigger configuration for casters 210 may provide additional stability, when compared to a configuration in which casters 210 are within the footprint of enclosure portion 202 (e.g., below enclosure portion 202). Further, the displacement of casters 210 along the width direction but not along the depth direction may allow for the total depth of tote 200 may be minimized, allowing for movement through narrow doors, elevators, etc. Further, the need for pallet jacks may be eliminated.

The configuration of casters 210 and isolators 206 shown may further allow tote 200 to have a reduced total height, easing travel in constrained spaces.

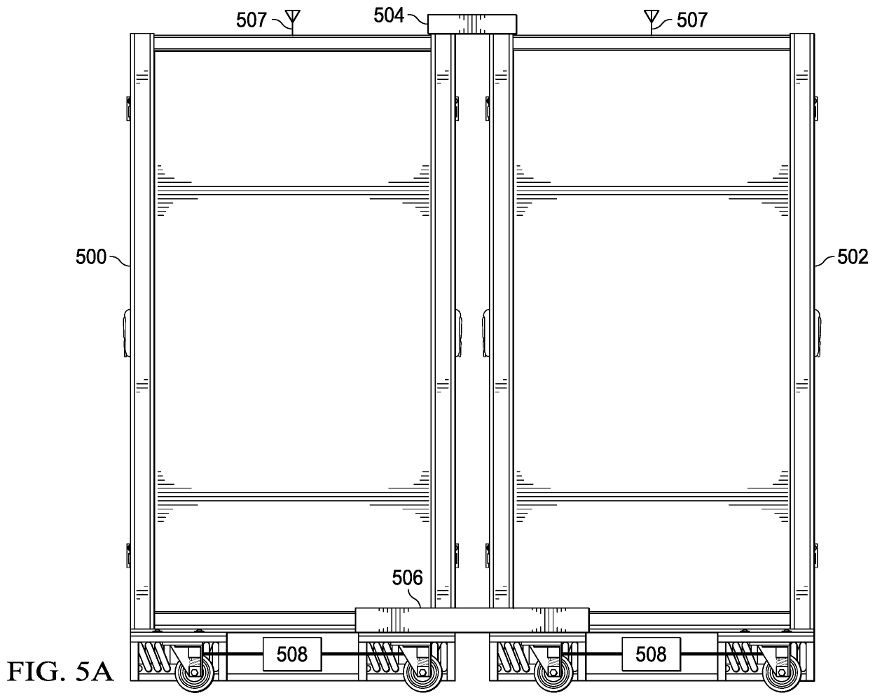

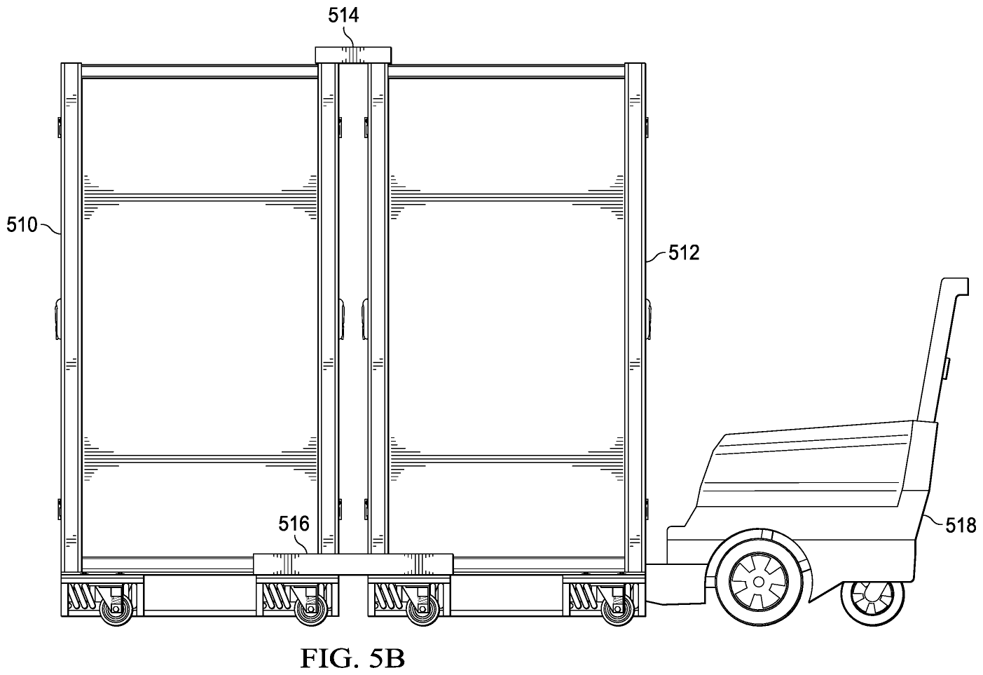

In these and other embodiments, casters 210 may comprise wheels that may be motorized. For example, as discussed below with reference to FIG. 5A, a tote may include one or more motors configured to drive such wheels.

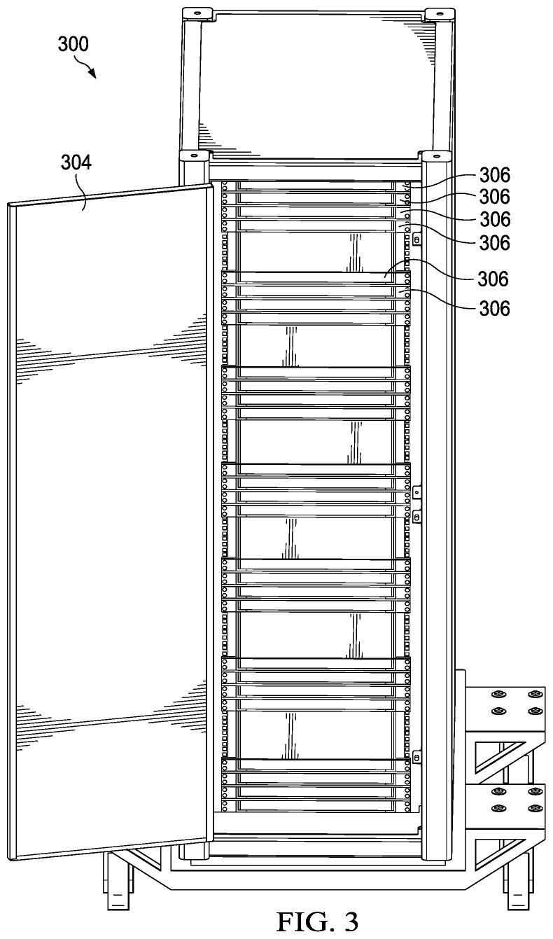

FIG. 3 shows an embodiment of a similar tote 300, in which door 304 has been opened. As can be seen in this view, a plurality of mounting features 306 are disposed within the enclosure portion of tote 300. For example, mounting features may include rails, shelves, or any other suitable hardware for securely attaching and/or retaining information handling systems.

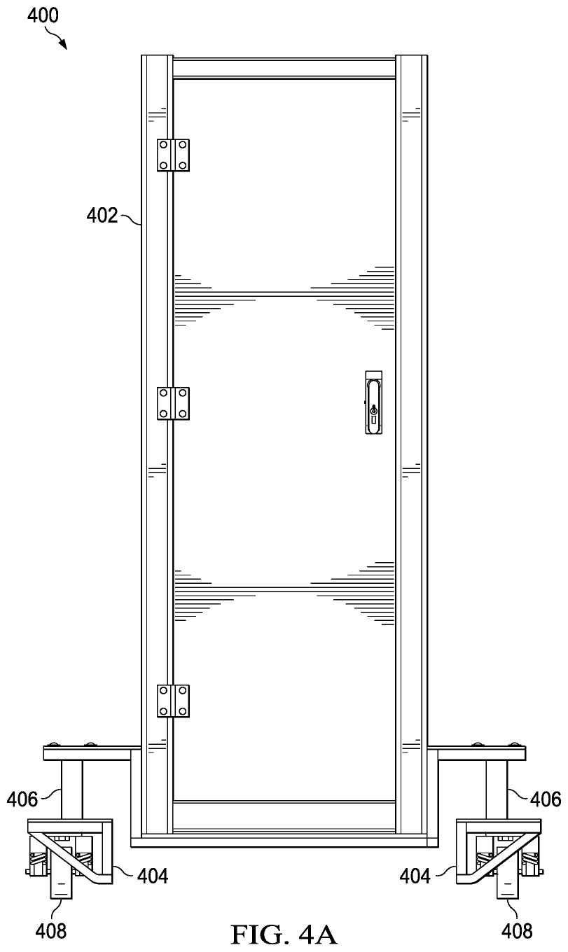

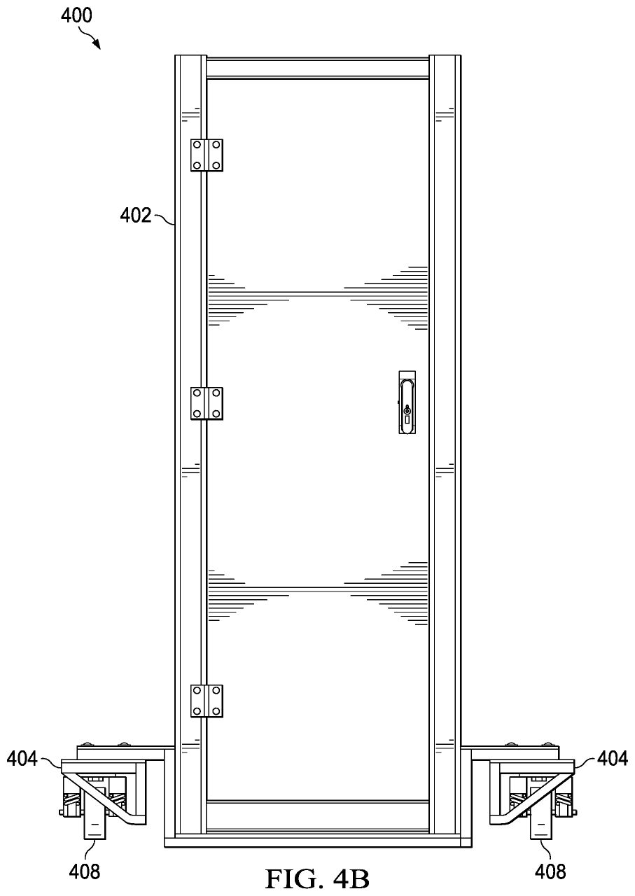

FIGS. 4A and 4B show front views of tote 400. Tote 400 may be generally similar to totes 200 and 300, except that tote 400 may be operable to change its height. FIG. 4A shows tote 400 in its raised position. This position may be used for example, to allow tote 400 to roll over a threshold or floor transition. Further, keeping tote 400 somewhat raised from its lowest position may allow a degree of travel in any shock or vibration dampers that may be present. For example, casters 408 may include spring dampers, and raising tote 400 away from the floor may allow such spring dampers to function during a shock event.

FIG. 4B shows tote 400 in its lowered position. This position may be used, for example, to allow tote 400 to pass through areas of low overhead clearance. As shown, the lowered position may include the ability to rest the bottom of enclosure 402 on the floor/ground. Such an ability may be advantageous when tote 400 is loaded into a truck or shipping container, for example, to prevent movement of tote 400 via casters 408 during transit.

Enclosure 402 of tote 400 may be coupled to base 404 (which may include casters 408) via one or more height adjustment mechanisms. In the embodiment shown, one height adjustment may be used above each of the four casters 408. In other embodiments, different arrangements may be used, as will be appreciated by one of ordinary skill in the art with the benefit of this disclosure. In some embodiments, base 404 may be a single, connected component that comprises all of the casters 408. In other embodiments, base 404 may comprise multiple portions that are not directly connected to one another.

Height adjustment mechanisms 406 may include, for example, hydraulic actuators. In these and other embodiments, height adjustment mechanisms 406 may include a telescoping member that may be disposed between a lower surface (e.g., a caster platform) and an upper surface (e.g., a horizontal member coupled to enclosure 402). In these and other embodiments, height adjustment mechanisms 406 may include one or more levers, scissor jacks, etc. In these and other embodiments, height adjustment mechanisms 406 may be actuated manually, motorized, actuated wirelessly, etc.

Other types of height adjustment mechanisms 406 and locations for height adjustment mechanisms 406 will be apparent to one of ordinary skill in the art with the benefit of this disclosure.

FIGS. 5A and 5B show some embodiments of motorized systems and methods for moving totes (e.g., while loading a shipping truck, moving totes within a datacenter, etc.). In these drawings, multiple totes are shown coupled together, as it may be convenient to move two or more totes at the same time. In other embodiments, totes may be moved individually without being coupled together.

As shown in FIG. 5A, totes 500 and 502 may be attached together via couplers 504 and 506. (Similarly in FIG. 5B, totes 510 and 512 may be attached together via couplers 514 and 516.) The use of such couplers may rigidly couple totes 500 and 502 together, allowing for simpler transportation of such totes. In various embodiments, either, both, or neither of such couplers may be employed. Coupler 504 may be attached to a top of totes 500 and 502, and coupler 506 may be attached to a bottom thereof (e.g., attached to one or more caster platforms). In other embodiments, different types of coupling may be employed. For example, non-rigid coupling (e.g., chains) may be used in some embodiments.

In some embodiments, couplers 504 and 506 may be bolted to totes 500 and 502 (e.g., manually). In these and other embodiments, couplers 504 and 506 may be attached to totes 500 and 502 via an electromechanical actuator. For example, such an actuator may receive a wireless signal operable to cause the actuator to secure itself to the respective totes and lock them in place. Another wireless signal may be employed to cause the actuator to release itself from the respective totes. Such wireless signals may be transmitted from, for example, a mobile device of a datacenter employee or shipper tasked with moving the totes. In some embodiments, rather than being bolted together, the couplers may be attached to the totes via the use of drop-in pins.

As shown in FIG. 5A, totes 500 and 502 may respectively include motors 508. Such motors may be mechanically coupled to one or more wheels of totes 500 and 502, allowing such wheels to be driven, turned, etc. as desired.

In some embodiments, totes 500 and 502 may be controlled wirelessly via antennas 507. For example, a shipper or a datacenter employee may remotely control the movement of totes 500 and 502 via a wireless device such as a smartphone. In other embodiments, voice control, etc. may be employed. In some embodiments, such remote control may be relatively direct, with the wireless device issuing commands such as forward, reverse, left, right, etc.

In other embodiments, however, totes 500 and 502 may include a degree of intelligence or autonomy. In such embodiments, the wireless device may issue higher-level commands such as telling the totes to travel to a given location, without specifying the details about how they should accomplish that goal. In such a situation, the totes may then autonomously execute path-finding algorithms and the like (e.g., including receiving input from one or more cameras mounted on the totes, on a flying drone, on the walls, or elsewhere). The totes may then travel to the desired destination without further input or micromanagement. Totes 500 and 502 may include on-board power supplies (e.g., batteries) that may be charged (e.g., inductively) while they are not in motion.

In the embodiment of FIG. 5B, totes 510 and 512 may not include motors 508 or antennas 507. In this embodiment, they may be manually moved via the use of a motorized dolly such as dolly 518. For example, dolly 518 may push or pull totes 510 and 512 into position.

Although various possible advantages with respect to embodiments of this disclosure have been described, one of ordinary skill in the art with the benefit of this disclosure will understand that in any particular embodiment, not all of such advantages may be applicable. In any particular embodiment, some, all, or even none of the listed advantages may apply.

This disclosure encompasses all changes, substitutions, variations, alterations, and modifications to the exemplary embodiments herein that a person having ordinary skill in the art would comprehend. Similarly, where appropriate, the appended claims encompass all changes, substitutions, variations, alterations, and modifications to the exemplary embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative.

Unless otherwise specifically noted, articles depicted in the drawings are not necessarily drawn to scale. However, in some embodiments, articles depicted in the drawings may be to scale.

Further, reciting in the appended claims that a structure is “configured to” or “operable to” perform one or more tasks is expressly intended not to invoke 35 U.S.C. § 112(f) for that claim element. Accordingly, none of the claims in this application as filed are intended to be interpreted as having means-plus-function elements. Should Applicant wish to invoke § 112(f) during prosecution, Applicant will recite claim elements using the “means for [performing a function]” construct.

All examples and conditional language recited herein are intended for pedagogical objects to aid the reader in understanding the invention and the concepts contributed by the inventor to furthering the art, and are construed as being without limitation to such specifically recited examples and conditions. Although embodiments of the present inventions have been described in detail, it should be understood that various changes, substitutions, and alterations could be made hereto without departing from the spirit and scope of the disclosure.

What is claimed is:

1. An apparatus comprising:
an enclosure that includes a plurality of mounting features that are configured to receive information handling systems; and
a base disposed below the enclosure, coupled to the enclosure, and including a plurality of wheels;
wherein the base is coupled to the enclosure via a height adjustment mechanism configured to lower and raise the enclosure relative to the base.

2. The apparatus of claim 1, wherein the enclosure and the mounting features are sized to receive information handling systems that conform to standardized rack unit sizes.

3. The apparatus of claim 1, wherein the height adjustment mechanism includes a hydraulic actuator.

4. The apparatus of claim 3, wherein the hydraulic actuator is configured to be actuated manually.

5. The apparatus of claim 3, further comprising a motor configured to actuate the hydraulic actuator.

6. The apparatus of claim 1, wherein the enclosure is configured to be lowered to a floor on which the wheels are disposed.

7. The apparatus of claim 1, further comprising a motor coupled to the plurality of wheels.

8. The apparatus of claim 7, wherein the motor and the wheels are operable to be controlled wirelessly.

9. The apparatus of claim 7, wherein the motor and the wheels are operable to autonomously move the apparatus from a first location to a second location.

10. The apparatus of claim 1, further comprising a locking mechanism configured to be coupled to a coupler, wherein the coupler is further configured to be coupled to another apparatus.

11. The apparatus of claim 10, wherein the apparatus and the another apparatus are configured to be moved from a first location to a second location by a motor.

12. The apparatus of claim 1, wherein the apparatus is configured for transportation of the information handling systems, but is not configured to allow for operation of the information handling systems while the information handling systems are received therein.

13. A method comprising:
forming an enclosure that includes a plurality of mounting features that are configured to receive information handling systems; and
coupling a base to the enclosure, wherein the base is disposed below the enclosure and includes a plurality of wheels;
wherein the base is coupled to the enclosure via a height adjustment mechanism configured to lower and raise the enclosure relative to the base.

14. The method of claim 13, wherein the enclosure and the mounting features are sized to receive information handling systems that conform to standardized rack unit sizes.

15. The method of claim 13, wherein the height adjustment mechanism includes a hydraulic actuator.

16. The method of claim 15, wherein the hydraulic actuator is configured to be actuated manually.

17. The method of claim 15, further comprising coupling a motor to the hydraulic actuator, the motor configured to actuate the hydraulic actuator.

18. The method of claim 17, wherein the motor and the wheels are operable to be controlled wirelessly.

19. The method of claim 17, wherein the motor and the wheels are operable to autonomously move the enclosure from a first location to a second location.

20. The method of claim 13, further comprising:
loading a plurality of information handling systems into the enclosure;
transporting the enclosure from a first location to a second location;
unloading the plurality of information handling systems from the enclosure; and
reusing the enclosure by loading a second, different plurality of information handling systems into the enclosure.
